(19) United States
(12) Patent Application Publication
(10) Pub. No.: US 2025/0391666 A1
(43) Pub. Date: Dec. 25, 2025

(54) RESIDUE REMOVAL AFTER ETCH PROCESSES USING A BORON-CONTAINING ETCHANT

(71) Applicant: Applied Materials, Inc., Santa Clara, CA (US)

(72) Inventors: Baiwei Wang, Santa Clara, CA (US); Xiaolin C. Chen, San Ramon, CA (US); Wanxing Xu, Sunnyvale, CA (US); Bo Wang, San Jose, CA (US); Zhenjiang Cui, San Jose, CA (US); Anchuan Wang, San Jose, CA (US)

(73) Assignee: Applied Materials, Inc., Santa Clara, CA (US)

(21) Appl. No.: 18/750,084

(22) Filed: Jun. 21, 2024

(51) Int. Cl. H01L 21/311; C09K 13/00; H01J 37/32

(52) U.S. Cl. CPC H01L 21/31116; C09K 13/00; H01J 37/32357; H01J 2237/335

(57) ABSTRACT

Exemplary semiconductor processing methods may include providing a boron-containing etchant precursor to a processing region of a semiconductor processing chamber. A substrate may be housed within the processing region. The methods may include providing a hydrogen-containing precursor, helium, or both to the processing region with the boron-containing etchant precursor. The methods may include contacting the substrate with the boron-containing etchant precursor and the hydrogen-containing precursor. The methods may include selectively removing at least a portion of a first material on the substrate relative to a second material second material on the substrate while removing an etch byproduct from one or more surfaces of the processing region.

### TECHNICAL FIELD

The present technology relates to semiconductor processes and equipment. More specifically, the present technology relates to etching materials and removing residue, such as etch byproduct.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. For example, a wet etch may preferentially remove some oxide dielectrics over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a boron-containing etchant precursor to a processing region of a semiconductor processing chamber. A substrate may be housed within the processing region. The methods may include providing a hydrogen-containing precursor, helium, or both to the processing region with the boron-containing etchant precursor. The methods may include contacting the substrate with the boron-containing etchant precursor and the hydrogen-containing precursor. The methods may include selectively removing at least a portion of a first material on the substrate relative to a second material second material on the substrate while removing an etch byproduct from one or more surfaces of the processing region.

In embodiments, the boron-containing etchant precursor may further include chlorine. The boron-containing etchant precursor may be or include boron trichloride (BCl₃). The hydrogen-containing precursor may be or include diatomic hydrogen (H₂). The methods may include providing an oxygen-containing precursor to the processing region with the boron-containing etchant precursor. The processing region may be maintained plasma-free. A flow rate of the hydrogen-containing precursor, a flow rate of helium, or both may be pulsed. A flow rate ratio of the hydrogen-containing precursor relative to a flow rate of the hydrogen-containing precursor and/or a flow rate of helium may be between about 1:10 and about 10:1. A temperature may be maintained at greater than or about 50° C. A pressure may be maintained at greater than or about 0.5 Torr.

Some embodiments of the present technology may encompass semiconductor processing methods. The methods may include providing a boron-containing etchant precursor to a processing region of a semiconductor processing chamber. A substrate may be housed within the processing region. The methods may include contacting the substrate with the boron-containing etchant precursor. The methods may include selectively removing at least a portion of a first material relative to a second material. Removing the portion of the first material may be performed plasma-free. Removing the portion of the first material may form an etch byproduct on one or more surfaces in the processing region. The methods may include providing a hydrogen-containing precursor to the processing region. The methods may include contacting surfaces in the processing region with the hydrogen-containing precursor, helium, or both. The contacting may remove a boron-containing byproduct from one or more surfaces in the processing region.

In embodiments, the etch byproduct may be or include a boron-and-oxygen-containing material or a boron-and-carbon-containing material. The hydrogen-containing precursor may be or include diatomic hydrogen (H₂). The methods may include providing a fluorine-containing precursor to the processing region with the hydrogen-containing precursor. The fluorine-containing precursor may be or include nitrogen trifluoride (NF₃). The methods may include forming plasma effluents of the hydrogen-containing precursor, the fluorine-containing precursor, or both.

Some embodiments of the present technology may encompass semiconductor processing methods. The methods may include providing a boron-containing etchant precursor to a processing region of a semiconductor processing chamber. A substrate may be housed within the processing region. The methods may include contacting the substrate with the boron-containing etchant precursor. The methods may include selectively removing at least a portion of a first material relative to a second material. Removing the portion of the first material may be performed plasma-free. Removing the portion of the first material may form an etch byproduct on one or more surfaces in the processing region. The methods may include contacting surfaces in the processing region with plasma effluents of a hydrogen-containing precursor, helium, or both. The contacting may remove a boron-containing byproduct from one or more surfaces in the processing region.

In embodiments, the plasma effluents of the hydrogen-containing precursor may be formed in a remote plasma system. The plasma effluents of the hydrogen-containing precursor may be formed in the processing region. A temperature may be maintained at less than or about 200° C.

Such technology may provide numerous benefits over conventional systems and techniques. For example, the processes may allow plasma-free etching to be performed that may protect features or materials on a substrate. Additionally, the processes may remove etch byproduct from one or more surfaces in a processing region that may hinder continued etching and/or contaminate the substrate being processed. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

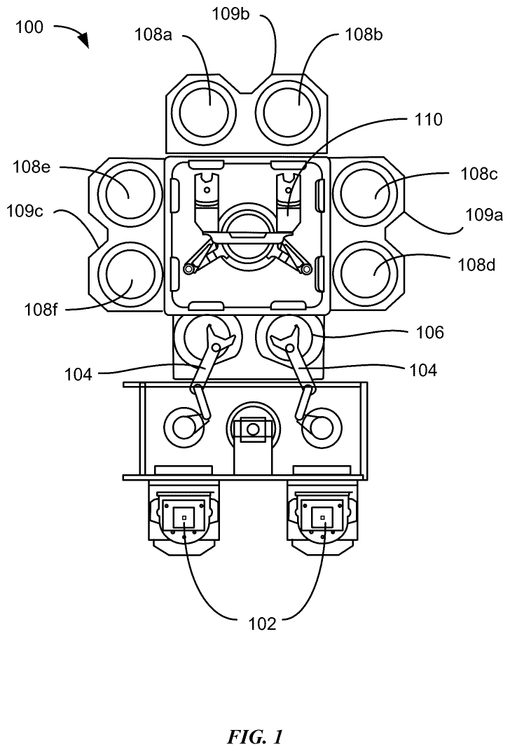

FIG. 1 shows a top plan view of one embodiment of an exemplary processing system according to some embodiments of the present technology.

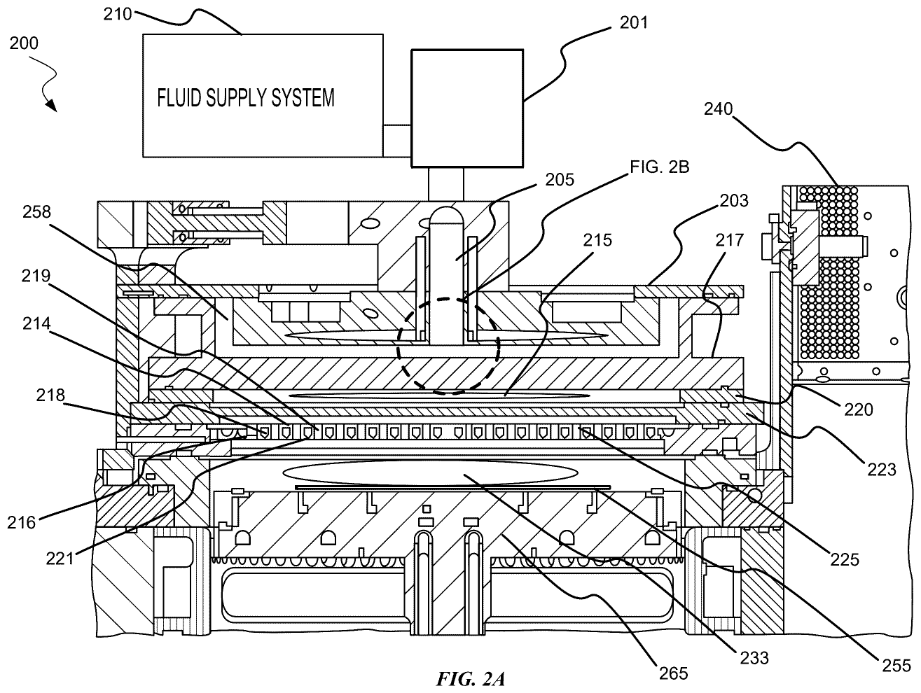

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

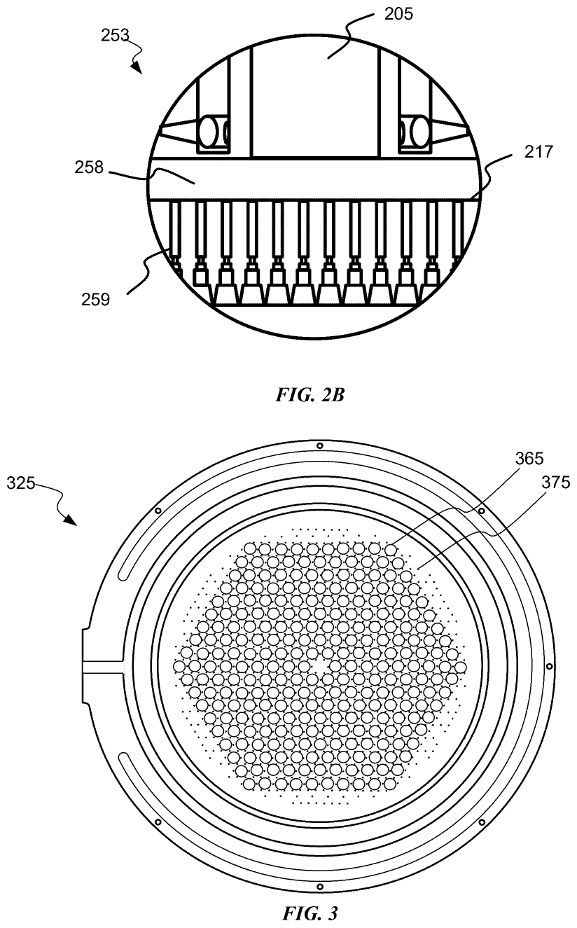

FIG. 3 shows a bottom plan view of an exemplary showerhead according to some embodiments of the present technology.

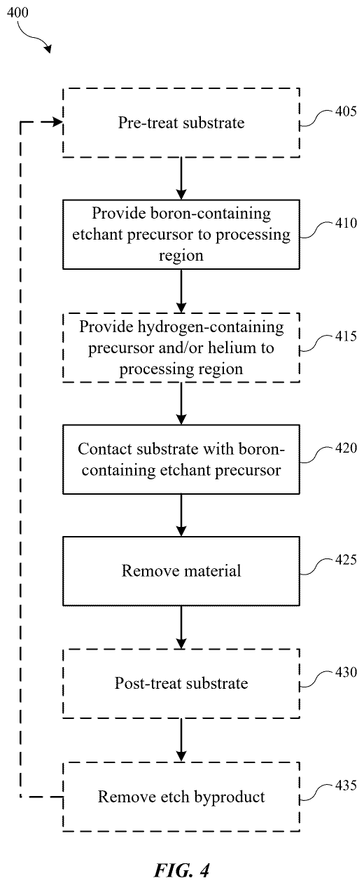

FIG. 4 shows exemplary operations in a method according to some embodiments of the present technology.

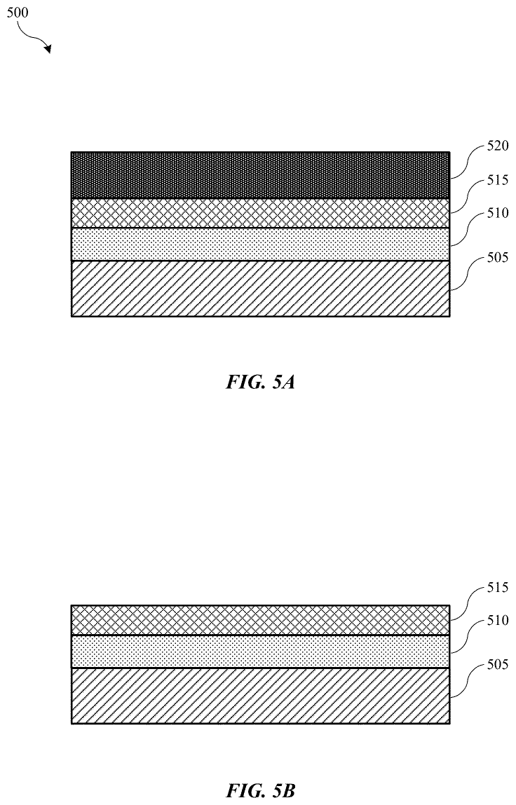

FIGS. 5A-5B show schematic cross-sectional views of materials etched according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include additional or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Diluted acids may be used in many different semiconductor processes for cleaning substrates and removing materials from those substrates. For example, diluted hydrofluoric acid (“DHF”) can be an effective etchant for silicon oxide, aluminum oxide, titanium oxide, and other materials, and may be used to remove these materials from substrate surfaces. After the etching or cleaning operation is complete, the acid may be dried from the wafer or substrate surface. Using DHF may be termed a “wet” etch where the diluent is often water. Additional etching processes may be used that utilize precursors delivered to the substrate. For example, plasma enhanced processes may also selectively etch materials by enhancing precursors through the plasma to perform a dry etch.

Although wet etchants using aqueous solutions or water-based processes may operate effectively for certain substrate structures, the water may pose challenges in a variety of conditions. For example, utilizing water during etch processes may cause issues when disposed on substrates including metal-containing materials. For example, certain later fabrication processes, such as recessing gaps, removing oxide dielectric, or other processes to remove oxygen-containing materials, may be performed after an amount of metallization has been formed on a substrate. If water is utilized in some fashion during the etching, an electrolyte may be produced, which when contacting the metal-containing material, may cause galvanic corrosion to occur between dissimilar metals, and the metal-containing material may be corroded or displaced in various processes. In addition, because of the surface tension of the water diluent, pattern deformation and collapse may occur with minute structures. The water-based material may also be incapable of penetrating some high aspect ratio features due to surface tension effects. Plasma etching may overcome the issues associated with water-based etching, although additional issues may occur. For example, a reactive ion etch process may expose the metal-containing material to ion activity, which through bombardment can damage the structure, and affect electrical characteristics. Additionally, some plasma etching may result in poor selectivity as other materials from the material to be etched may also be removed. Further, some etching operations use precursors that leave a residue that may impact final device performance.

The present technology overcomes these issues by performing a dry etch process that may be performed thermally, or without plasma. Additionally, the present technology may use specific halogen precursors, such as chlorine-containing precursors, that may leave reduced amounts of residue after etching is complete. By utilizing particular precursors and/or processing conditions that may facilitate halogen dissociation to provide etchant materials, an etch process may be performed that may protect the surrounding structures. Additionally, the materials and conditions used may allow improved etching, such as etch rates and selectivity, relative to conventional techniques. Further, by controlling an amount of etch byproduct, either during the etching or subsequent to the etching, an etch rate of the material to be removed may be maintained. Additionally, contamination of the structure being processed may be reduced and/or prevented by preventing excessive formation of etch byproduct.

Although the remaining disclosure will routinely identify specific etching processes utilizing the disclosed technology, it will be readily understood that the systems and methods are equally applicable to deposition and cleaning processes as may occur in the described chambers, as well as other etching technology and other etching that may be performed with a variety of exposed materials that may be maintained or substantially maintained. Accordingly, the technology should not be considered to be so limited as for use with the exemplary etching processes or chambers alone. Moreover, although an exemplary chamber is described to provide foundation for the present technology, it is to be understood that the present technology can be applied to virtually any semiconductor processing chamber that may allow the operations described.

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a pedestal 265 or substrate support, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may include aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the showerhead 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

The chamber discussed previously may be used in performing exemplary methods including etching methods. Turning to FIG. 4, exemplary operations in a method 400 according to embodiments of the present technology are illustrated. Method 400 may include one or more operations prior to the initiation of the method, including front end processing, deposition, gate formation, etching, polishing, cleaning, or any other operations that may be performed prior to the described operations. The method may include a number of optional operations, which may or may not be specifically associated with some embodiments of methods according to the present technology. For example, many of the operations are described in order to provide a broader scope of the processes performed, but are not critical to the technology, or may be performed by alternative methodology as will be discussed further below. Method 400 may describe operations shown schematically in FIGS. 5A-5B, the illustrations of which will be described in conjunction with the operations of method 400. It is to be understood that the figures illustrate only partial schematic views, and a substrate may contain any number of additional materials and features having a variety of characteristics and aspects as illustrated in the figures.

Method 400 may or may not involve optional operations to develop the semiconductor structure to a particular fabrication operation. It is to be understood that method 400 may be performed on any number of semiconductor structures 500 or substrates 505, as illustrated in FIG. 5A, including exemplary structures on which a material removal operation, such as a metal-containing material removal operation, may be performed. Exemplary semiconductor structures may include a trench, via, or other recessed features that may include one or more exposed materials. Additionally, exemplary semiconductor structures may include logic or memory structures, such as 3D NAND or DRAM structures. For example, an exemplary substrate 505 may contain silicon or some other semiconductor substrate material as well as one or more layers of material formed on the substrate 505. As illustrated in FIG. 5A, a first material 510 and a second material 515 may be formed on the substrate 505. Both the first material 510 and the second material 515 may have an exposed region. Additionally, a third material 520, such as a metal-containing material, may also be formed on the substrate 505 and may also include an exposed region.

The first material 510, the second material 515, and the third material 520 may be or include a low-k material, such as a silicon-containing material (e.g., silicon, silicon-and-oxygen-containing material, silicon-and-germanium-containing material, silicon-and-nitrogen-containing material, etc.), an oxide (e.g., hafnium-and-oxygen-containing material, aluminum-and-oxygen-containing material, etc.), a hardmask material (e.g., carbon hardmask material), or any other material that may be present on a substrate with the metal-containing material. For example, in one exemplary embodiment, the first material 510 may be a silicon-and-oxygen-containing material, such as silicon oxide (SiO₂), and the second material 515 may be a hafnium-and-oxygen-containing material, such as hafnium oxide (HfO). In some embodiments, as previously discussed, the third material 520 may be a metal-containing material. The metal-containing material may be or include a metal, but may also further include oxygen, nitrogen, or both. In embodiments, the metal may be tungsten, molybdenum, niobium, titanium, or any other metal. Other metal-containing materials may include, for example, tungsten-and-oxygen-containing material, tungsten-and-nitrogen-containing material, molybdenum-and-oxygen-containing material, molybdenum-and-nitrogen-containing material, niobium-and-oxygen-containing material, niobium-and-nitrogen-containing material, titanium-and-oxygen-containing material, or titanium-and-nitrogen-containing material. In one exemplary embodiment, the metal-containing material may be tungsten metal (W), molybdenum metal (Mo), or titanium-and-nitrogen-containing material, such as titanium nitride (TiN).

It is to be understood that the noted structure is not intended to be limiting, and any of a variety of other semiconductor structures, such as those including metal-containing materials, are similarly encompassed. Other exemplary structures may include two-dimensional and three-dimensional structures common in semiconductor manufacturing, and within which a material, such as a metal-containing material, is to be removed relative to one or more other materials, as the present technology may selectively remove materials, such as metal-containing materials, relative to other exposed materials, such as silicon-containing materials, other metal-containing materials, oxides, and nitrides, as well as any of the other materials discussed elsewhere. Additionally, although a high-aspect-ratio structure may benefit from the present technology, the technology may be equally applicable to lower aspect ratios and any other structures.

For example, layers of material according to the present technology may be characterized by any aspect ratios or the height-to-width ratio of the structure, although in some embodiments, the materials may be characterized by larger aspect ratios, which may not allow sufficient etching utilizing conventional technology or methodology. For example, in some embodiments the aspect ratio of any layer of an exemplary structure may be greater than or about 2:1, greater than or about 3:1, greater than or about 4:1, greater than or about 5:1, greater than or about 10:1, greater than or about 20:1, greater than or about 30:1, greater than or about 40:1, greater than or about 50:1, or greater. Additionally, each layer may be characterized by a reduced width or thickness less than or about 100 nm, less than or about 80 nm, less than or about 60 nm, less than or about 50 nm, less than or about 40 nm, less than or about 30 nm, less than or about 20 nm, less than or about 10 nm, less than or about 5 nm, less than or about 1 nm, or less, including any fraction of any of the stated numbers, such as 20.5 nm, 1.5 nm, etc. This combination of high aspect ratios and minimal thicknesses may frustrate many conventional etching operations, or require substantially longer etch times to remove a layer along a vertical or horizontal distance through a confined width. Moreover, damage to or removal of other exposed layers may occur with conventional technologies as well.

Method 400 may be performed to remove an exposed material, such as any number of metal materials, metal-containing materials, metal-and-nitrogen-containing materials, or metal-and-oxygen-containing materials, in any number of structures in embodiments of the present technology. The methods may include specific operations for the removal of materials, such as metal-containing materials, and may include one or more optional operations to prepare or treat the metal-containing materials. For example, an exemplary structure 500 or substrate 505 may have previous processing residues on the material to be removed. For example, residual photoresist or byproducts from previous processing may reside on the materials, such as the metal-containing materials. These materials may prevent access to the material to be removed, such as the metal-containing material, or may interact with etchants differently than a clean material surface, which may frustrate one or more aspects of the etching. Accordingly, in some embodiments, an optional pre-treatment of the material may occur at optional operation 405. Exemplary pre-treatment operations may include a thermal treatment, wet treatment, or plasma treatment, for example, which may be performed in chamber 200 as well as any number of chambers that may be included on system 100 described above.

In one exemplary plasma pre-treatment, a remote or local plasma may be developed from a precursor intended to interact with residues in one or more ways. For example, utilizing chambers such as chamber 200 described above, either a remote or local plasma may be produced from one or more precursors. For example, an oxygen-containing precursor, a hydrogen-containing precursor, a nitrogen-containing precursor, a helium-containing precursor, or some other precursor may be flowed into a remote plasma region or into the processing region, where a plasma may be struck. The plasma effluents may be flowed to the substrate 505, and may contact the residue material. The plasma process may be either physical or chemical depending on the material to be removed to expose the material to be etched, such as the metal-containing material. For example, plasma effluents may be flowed to contact and physically remove the residue, such as by a sputtering operation, or the precursors may be flowed to interact with the residues to produce volatile byproducts that may be removed from the chamber.

Exemplary precursors used in the pre-treatment may be or include hydrogen, a hydrocarbon, water vapor, an alcohol, hydrogen peroxide, or other materials that may include hydrogen as would be understood by the skilled artisan. Exemplary oxygen-containing precursors may include molecular oxygen, ozone, nitrous oxide, nitrous oxide, or other oxygen-containing materials. Nitrogen gas may also be used, or a combination precursor having one or more of hydrogen, oxygen, and/or nitrogen may be utilized to remove particular residues. Once the residue or byproducts have been removed, a clean material surface, such as a metal-containing surface, may be exposed for etching.

At operation 410 of method 400, an etchant precursor may be provided to the processing region of the semiconductor processing chamber. The etchant precursor may be flowed through a remote plasma region of the processing chamber, such as region 215 described above, although in some embodiments, method 400 may not utilize plasma effluents during the etching operations. For example, method 400 may flow the etchant precursor to the substrate 505 without exposing the precursor to a plasma, and may perform the removal of the third material 520 without production of plasma effluents. However, in some embodiments the etchant precursor may be plasma-enhanced, which may occur in a remote plasma region to protect materials on the substrate 505 from contact with plasma effluents. The plasma may also be formed locally if there is no concern with protecting materials on the substrate from contact with plasma effluents.

In embodiments, an oxygen-containing precursor may be provided to the processing region with the etchant precursor. Similar to the etchant precursor, the oxygen-containing precursor may be flowed through the remote plasma region of the processing chamber, such as region 215 described above, although in some embodiments, method 400 may not utilize plasma effluents during the etching operations. For example, method 400 may flow the oxygen-containing precursor to the substrate 505 without exposing the precursor to a plasma, and may perform the removal of the third material 520 without production of plasma effluents. However, in some embodiments the oxygen-containing precursor may be plasma-enhanced, which may occur in a remote plasma region to protect materials on the substrate 505 from contact with plasma effluents. The plasma may also be formed locally if there is no concern with protecting materials on the substrate from contact with plasma effluents. The oxygen-containing precursor may be provided with the etchant precursor or may be provided separately. As such, one of the oxygen-containing precursor or the etchant precursor may be provided to the remote plasma region of the processing chamber, such as region 215, while the other bypasses the remote plasma region and may be provided to the substrate 505.

At optional operation 415 of method 400, a hydrogen-containing precursor, helium, or both may be provided to the processing region of the semiconductor processing chamber. Again, similar to the etchant precursor, the hydrogen-containing precursor and/or helium may be flowed through the remote plasma region of the processing chamber, such as region 215 described above, although in some embodiments, method 400 may not utilize plasma effluents during the etching operations. For example, method 400 may flow the hydrogen-containing precursor and/or helium to the substrate 505 without exposing the precursor to a plasma, and may perform the removal of the third material 520 without production of plasma effluents. However, in some embodiments the hydrogen-containing precursor and/or helium may be plasma-enhanced, which may occur in a remote plasma region to protect materials on the substrate 505 from contact with plasma effluents. The plasma may also be formed locally if there is no concern with protecting materials on the substrate 505 from contact with plasma effluents. The hydrogen-containing precursor and/or helium may be provided with the etchant precursor and, if present, the oxygen-containing precursor or may be provided separately. As such, some of the precursors may be provided to the remote plasma region of the processing chamber, such as region 215, while some of the precursors may bypass the remote plasma region and is provided to the substrate 505.

At operation 420, method 400 may include contacting the substrate 505 with the etchant precursor and, if present, the oxygen-containing precursor. When present, the oxygen-containing precursor may contact the substrate 505, including exposed third material 520, and may produce an oxidized third material, which may remain on the substrate 505. The etchant precursor may donate one or more etchant atoms, such as a halogen atom, while accepting one or more oxygen atoms in some embodiments, resulting in etching or removal of the oxidized third material. Thus, as illustrated in FIG. 5B, method 400 may include removing at least a portion of the third material 520 at operation 425. The removal may be relative to another material, such as first material 510 and/or second material 515. Removing the portion of the third material may form an etch byproduct on one or more surfaces in the processing region.

The etching or removal of the third material 520 may result in formation of etch byproduct. The etch byproduct may not be fully removed or purged from the processing region. As such, the etch byproduct may form or deposit on one or more surfaces in the processing region. If left untreated, the etch byproduct may accumulate. Eventually, the etch byproduct may impact the etching operation, reducing the etch rate or halting the etch entirely. The etch byproduct may also contaminate the substrate 505 if residue is incorporated into structure 500. The hydrogen-containing precursor and/or helium provided at optional operation 415 may react with the etch byproduct to form volatiles that may be removed from the processing region. For example, when the etchant precursor includes a boron-containing etchant precursor, the etch byproduct may include boron-and-carbon-containing material or boron-and-oxygen-containing material. The hydrogen-containing precursor may react with the boron-and-carbon-containing material or boron-and-oxygen-containing material to form carbon-and-hydrogen-containing gases or hydrogen-and-oxygen-containing gases, respectively, which may more easily be removed from the processing region. By including helium, a residence time of the hydrogen-containing precursor on a surface of the etch byproduct may be increased.

As noted above, the present technology may be performed without plasma development during operations 410-425. By utilizing particular precursors, and performing the etching within certain process conditions, a plasma-free removal may be performed, and the removal may also be a dry etch. Accordingly, techniques according to aspects of the present technology may be performed to remove third material 520 from narrow features, as well as high aspect ratio features, and thin dimensions that may otherwise be unsuitable for wet etching. An optional operation may be performed to clear the substrate or chamber of residues and may include a post-treatment at optional operation 430. The post-treatment may include similar operations as the pre-treatment, and may include any of the precursors or operations discussed above for the pre-treatment. The post-treatment may clear residual etchant, such as chlorine, from the substrate or chamber in some embodiments. It is to be understood that although the pre-treatment and/or post-treatment operations may include plasma generation and plasma effluent delivery to the substrate, plasma may not be formed during operations 410-425. For example, in some embodiments no plasma may be generated while the etchant precursor or precursors are being delivered into the processing chamber.

Method 400 may include an additional or alternative operation to remove etch byproduct at optional operation 435. Method 400 may include halting a flow rate any precursors prior to optional operation 435. Method 400 may include purging the processing region after halting the flow rate of any precursors. At optional operation 435, in addition or alternative to optional operation 415, method 400 may include providing the hydrogen-containing precursor to the processing region and contacting surfaces in the processing region with the hydrogen-containing precursor. In embodiments, a fluorine-containing precursor may be provided to the processing region with the hydrogen-containing precursor. As previously discussed, the hydrogen-containing precursor and, if present, the fluorine-containing precursor may react with the etch byproduct to form volatiles that may be removed from the processing region. Again, for example, when the etchant precursor includes a boron-containing etchant precursor, the etch byproduct may include boron-and-carbon-containing material or boron-and-oxygen-containing material. The hydrogen-containing precursor and, if present, the fluorine-containing precursor may react with the boron-and-carbon-containing material or boron-and-oxygen-containing material to form carbon-and-hydrogen-containing gases or hydrogen-and-oxygen-containing gases, respectively, which may more easily be removed from the processing region. Additional fluorine-containing gases may be formed which may also be removed from the processing region. For example, if the etch byproduct includes boron-and-carbon-containing material or boron-and-oxygen-containing material, the fluorine-containing precursor may form boron-and-fluorine-containing gases which may more easily be removed from the processing region.

Like other operations of method 400, optional operation 435 may be maintained plasma-free. Instead, optional operation 435 may be a thermal reaction between the hydrogen-containing precursor and, if present, the fluorine-containing precursor and the etch byproduct. However, it is also contemplated that plasma effluents of the hydrogen-containing precursor and, if present, the fluorine-containing precursor may be formed. In embodiments, the substrate 505 being processed may be removed prior to removing etch byproduct at optional operation 435. As such, the use of plasma effluents may not impact the substrate 505 or layers formed on the substrate 505. If formed, the plasma effluents of the hydrogen-containing precursor and, if present, the fluorine-containing precursor may be formed in the remote plasma region or locally in the processing region.

The etchant precursor provided at operation 410 may include halogen-containing precursors, and may include one or more of bromine, chlorine, or fluorine in some embodiments. The specific precursors may be based on bonding or stability of the precursors. An exemplary etchant precursor may include a boron-containing etchant precursor, such as boron trichloride (BCl₃), as well as halogen-containing precursors such as other bromine-containing precursors, chlorine-containing precursors, or fluorine-containing precursors. Other halogen-containing precursors may include hydrogen bromide (HBr), thionyl bromide (SOBr₂), sulfuryl bromide (SO₂Br₂), bromotrichloromethane (CCl₃Br), diatomic chlorine (Cl₂), hydrogen chloride (HCl), carbon tetrachloride (CCl₄), phosphorus pentachloride (PCl₅), thionyl chloride (SOCl₂), sulfuryl chloride (SO₂Cl₂), diatomic fluorine (F₂), nitrogen trifluoride (NF₃), sulfur hexafluoride (SF₆), tungsten hexafluoride (WF₆), or any other halogen-containing material used or useful in semiconductor processing.

When provided, the oxygen-containing precursor provided with the etchant precursor may be any oxygen-containing material used or useful in semiconductor processing. For example, the oxygen-containing precursor may be or include atomic oxygen (O), molecular oxygen (O₂), ozone (O₃), nitrogen dioxide (NO₂), nitrous oxide (N₂O), water or steam (H₂O), or hydrogen peroxide (H₂O₂).

The etchant precursor as well as the oxygen-containing precursor and/or the hydrogen-containing precursor, if present, may also be provided with any number of carrier gases, which may include nitrogen, helium, argon, or other noble, inert, or useful precursors. The carrier gases may serve to dilute the etchant precursor, which may control etch rate, as well as distribute the etchant precursor and/or control pressure.

Flow rates of the etchant precursor may be tuned, including in situ, to control the etch process. For example, a flow rate of the etchant precursor may be reduced, maintained, or increased during the etching operations. By increasing the flow rate of the etchant precursor, etch rates may be increased up to a point of saturation. During any of the operations of method 400, the flow rate of the etchant precursor may be between about 5 sccm and about 1,000 sccm. Additionally, the flow rate of the etchant precursor may be maintained less than or about 900 sccm, less than or about 800 sccm, less than or about 700 sccm, less than or about 600 sccm, less than or about 500 sccm, less than or about 400 sccm, or less. However, to maintain an amount of etchant precursor in the processing region to expedite the desired etching, the flow rate of the etchant precursor may be greater than or about 250 sccm, greater than or about 500 sccm, greater than or about 600 sccm, greater than or about 700 sccm, greater than or about 800 sccm, or more. The flow rate of the etchant precursor may also be between any of these stated flow rates, or within smaller ranges encompassed by any of these numbers.

A flow rate ratio of the oxygen-containing precursor relative to the etchant precursor may be greater than or about 2:1, greater than or about 2.2:1, greater than or about 2.4:1, greater than or about 2.6:1, greater than or about 2.8:1, greater than or about 3:1, or more. As previously discussed, the oxygen-containing precursor may oxidize the third material 520, which may then be etched with the etchant precursor. Accordingly, sufficient oxygen-containing material may be necessary to ensure oxidation of third material 520. Some materials of third material 520, such as some metal-containing materials, contemplated by the present technology may be difficult to oxidize and may require a large amount of oxygen. As such, a flow rate of the oxygen-containing precursor may be greater than or about 1,000 sccm, greater than or about 1,200 sccm, greater than or about 1,400 sccm, greater than or about 1,600 sccm, greater than or about 1,800 sccm, greater than or about 2,000 sccm, greater than or about 2,200 sccm, greater than or 2,400 sccm, or more.

The hydrogen-containing precursor provided at optional operation 415 and/or optional operation 435 may be any hydrogen-containing material previously discussed. In exemplary embodiments, the hydrogen-containing precursor may be or include diatomic hydrogen (H₂). The fluorine-containing precursor provided at optional operation 435 may be any fluorine-containing material previously discussed. In exemplary embodiments, the hydrogen-containing precursor may be or include F₂ or NF₃.

A flow rate ratio of the hydrogen-containing precursor and/or helium relative to the etchant precursor, such as at optional operation 415, may be greater than or about 1:10, greater than or about 1:5, greater than or about 2:5, greater than or about 1:2, greater than or about 3:5, greater than or about 4:5, greater than or about 1:1, greater than or about 2:1, greater than or about 4:1, greater than or about 5:1, greater than or about 6:1, greater than or about 8:1, greater than or about 10:1, or more. As previously discussed, the hydrogen-containing precursor and/or helium may volatize etch byproduct that may form on one or more surfaces in the processing region, which may reduce etch rate or introduce residue to the substrate 505 if not removed. Accordingly, sufficient hydrogen-containing material and/or helium may be necessary to ensure control over the formation of etch byproduct. As such, a flow rate of the hydrogen-containing precursor and/or helium may be greater than or about 250 sccm, greater than or about 500 sccm, greater than or about 750 sccm, greater than or about 1,000 sccm, greater than or about 1,200 sccm, greater than or about 1,400 sccm, greater than or about 1,600 sccm, greater than or 1,800 sccm, greater than or 2,000 sccm, greater than or 2,500 sccm, or more.

In embodiments, a flow rate of the hydrogen-containing precursor and/or helium may be pulsed. Excessive hydrogen and/or helium may dilute the etchant precursor and may reduce an etch rate of the third material 520. As such, to maintain an amount or concentration of etchant precursor, the low rate of the hydrogen-containing precursor and/or helium may be pulsed to limit an amount or concentration hydrogen-containing precursor and/or helium.

Processing conditions may impact and facilitate etching according to the present technology. Because the etch reaction may proceed based on thermal dissociation of a halogen from the etchant precursor, the temperatures may be at least partially dependent on the particular halogen and/or other atoms of the etchant precursor in order to initiate dissociation. As temperature increases above or about 250° C., for example, etching begins to occur or increase, which may indicate dissociation of the precursor, and/or activation of the reaction with the material to be etched, such as the metal-containing material. As temperature continues to increase, dissociation may be further facilitated as may the reaction with the material to be etched, such as the metal-containing material. Accordingly, higher temperatures may increase the etch rate of the material to be etched, such as the metal-containing material, but may also reduce the selectivity as other materials may begin to etch at a higher rate.

In embodiments, the method may be performed on substrates that may have a number of produced features, which may produce a thermal budget. Thus, in some embodiments of the present technology, etching methods may be performed at substrate, pedestal, and/or chamber temperatures less than or about 650° C., and may be performed at temperatures less than or about 600° C., less than or about 575° C., less than or about 550° C., less than or about 525° C., less than or about 500° C., less than or about 490° C., less than or about 480° C., less than or about 470° C., less than or about 460° C., less than or about 450° C., less than or about 440° C., less than or about 430° C., less than or about 420° C., less than or about 410° C., less than or about 400° C., less than or about 380° C., less than or about 360° C., less than or about 340° C., less than or about 320° C., less than or about 300° C., or lower. The temperature may also be maintained at any temperature within these ranges, within smaller ranges encompassed by these ranges, or between any of these ranges. Additionally, as previously discussed, while a greater temperature may increase an etch rate of the third material 520, selectivity may suffer. Accordingly, in some embodiments, the methods may be performed at temperatures greater than or about 250° C., and may be performed at temperatures greater than or about 275° C., greater than or about 300° C., greater than or about 310° C., greater than or about 320° C., greater than or about 330° C., greater than or about 340° C., greater than or about 350° C., greater than or about 360° C., greater than or about 370° C., greater than or about 380° C., greater than or about 390° C., greater than or about 400° C., or higher.

The pressure within the chamber may also affect the operations performed as well as affect at what temperature the etchant precursor may dissociate. Accordingly, in some embodiments the pressure may be maintained at greater than or about 0.5 Torr, greater than or about 1 Torr, greater than or about 2 Torr, greater than or about 3 Torr, greater than or about 4 Torr, greater than or about 5 Torr, greater than or about 6 Torr, greater than or about 7 Torr, greater than or about 8 Torr, greater than or about 9 Torr, greater than or about 10 Torr, greater than or about 15 Torr, greater than or about 20 Torr, greater than or about 25 Torr, greater than or about 30 Torr, greater than or about 40 Torr, greater than or about 50 Torr, greater than or about 60 Torr, or higher. Additionally, the pressure may be maintained at less than or about 50 Torr, less than or about 40 Torr, less than or about 30 Torr, less than or about 25 Torr, less than or about 20 Torr, less than or about 15 Torr, less than or about 10 Torr, less than or about 9 Torr, less than or about 8 Torr, less than or about 7 Torr, less than or about 6 Torr, less than or about 5 Torr, less than or about 4 Torr, less than or about 3 Torr, less than or about 2 Torr, less than or about 1 Torr, less than or about 0.1 Torr, or less. The pressure may also be maintained at any pressure within these ranges, within smaller ranges encompassed by these ranges, or between any of these ranges. In some embodiments, etch amount may be facilitated and may initiate as pressure increases. Additionally, as pressure continues to increase, etching may improve up to a point before beginning to reduce, and eventually cease as pressure continues to increase.

Without being bound to any particular theory, pressure within the chamber may affect processing with precursors described above. At low pressures, flow across a substrate may be reduced, and dissociation may similarly be reduced. As pressure increases, interactions between the etchant precursor and the substrate may increase, which may increase reactions and etch rates. However, as pressure continues to increase, recombination of the dissociated etchant precursor atoms may increase due to the relative stability of the molecules. Thus, the precursors may effectively be pumped back out of the chamber without reacting with the substrate 505 or materials on the substrate 505. Additionally, interactions with the material to be etched, such as third material 520, may be suppressed as pressure continues to increase, or byproduct material, such as metal-and-halogen-containing material, may be reintroduced to the material being etched, such as the metal-containing material, further limiting removal. Accordingly, in some embodiments, pressure within the processing chamber may be maintained below or about 100 Torr.

While temperature and/or pressure may be maintained constant during an entirety of method 400, some embodiments may include adjusting temperature and/or pressure between operations 410-425 and optional operation 435. That is, removing etch byproduct at optional operation 435 may be performed at a different temperature and/or pressure than during the etching at operations 410-425. In embodiments in which optional operation 435 is performed plasma-free, etch byproduct removal may be performed at substrate, pedestal, and/or chamber temperatures greater than or about 50° C., and may be performed at temperatures greater than or about 60° C., greater than or about 70° C., greater than or about 80° C., greater than or about 90° C., greater than or about 100° C., greater than or about 110° C., greater than or about 120° C., greater than or about 130° C., greater than or about 140° C., greater than or about 150° C., greater than or about 175° C., greater than or about 200° C., or more, or any of the temperatures previously discussed. Increased temperatures may be necessary to form volatiles and remove the etch byproduct during thermal processing. However, if optional operation 435 is plasma-enhanced, a lower temperature may be utilized. In plasma-enhanced operations, etch byproduct removal may be performed at substrate, pedestal, and/or chamber temperatures less than or about 200° C., and may be performed at temperatures less than or about 175° C., less than or about 150° C., less than or about 125° C., less than or about 100° C., less than or about 90° C., less than or about 80° C., less than or about 70° C., less than or about 60° C., less than or about 50° C., or less.

If optional operation 435 is plasma-enhanced, plasma effluents of the hydrogen-containing precursor and, if present, the fluorine-containing precursor may be formed at between about 0 W and about 1,000 W. The plasma effluents may be a capacitively coupled plasma effluent. In embodiments, the plasma power may be greater than or about 50 W, and may be greater than or about 100 W, greater than or about 150 W, greater than or about 200 W, greater than or about 250 W, greater than or about 300 W, greater than or about 400 W, greater than or about 500 W, or more. Similarly, the plasma power may be less than or about 500 W, and may be less than or about 400 W, less than or about 300 W, less than or about 250 W, less than or about 200 W, less than or about 150 W, less than or about 100 W, less than or about 50 W, or less. At higher plasma powers, rate of etch byproduct removal may increase. Conversely, at lower plasma powers, rate of etch byproduct removal may decrease, but a longer duration of optional operation 435 may remove a similar amount of etch byproduct as a higher plasma power.

In embodiments, an etch rate of the third material 520 may be greater than or about 5 Å per minute, greater than or about 10 Å per minute, greater than or about 25 Å per minute, greater than or about 50 Å per minute, greater than or about 70 Å per minute, greater than or about 100 Å per minute, or more. As previously discussed, higher temperatures and certain pressures may increase the etch rate of the third material 520. Additionally, third material 520, which may be a metal material, may etch at a faster rate than transition metal oxides or transition metal nitrides. Thus, depending on the third material 520 to be etched, the etch rate may be maintained at any etch rate within these ranges, within smaller ranges encompassed by these ranges, or between any of these ranges.

By performing operations according to embodiments of the present technology, third material 520 may be etched selectively relative to other materials, including other oxides or nitrides or any of the materials previously discussed with regard to the first material 510 and the second material 515. For example, the present technology may selectively etch third material 520 relative to the second material at a selectivity of greater than or about 2:1, greater than or about 3:1, greater than or about 4:1, greater than or about 5:1, greater than or about 6:1, greater than or about 7:1, greater than or about 8:1, greater than or about 9:1, greater than or about 10:1, greater than or about 15:1, greater than or about 20:1, greater than or about 25:1, greater than or about 30:1, greater than or about 35:1, greater than or about 40:1, greater than or about 45:1, greater than or about 50:1, or more. For example, etching performed according to some embodiments of the present technology may etch third material 520 while substantially or essentially maintaining other materials, such as silicon oxide or other materials, such as nitrides or oxides of silicon, aluminum, or hafnium, or materials such as polysilicon for example.

Selectivity may be based in part on precursors used and the ability to dissociate at more controlled temperature ranges. Conventional plasma-enhanced etches may be incapable of producing etch selectivity achievable by embodiments of the present technology. Similarly, because wet etchants readily remove low-k materials, wet etchants may also be incapable of etching selectively at rates comparable to embodiments of the present technology. The previously discussed methods may allow the removal of materials, such as metal-containing materials, relative to a number of other exposed materials. By utilizing techniques of the present technology as previously described, improved etching of materials, such as metal-containing materials, may be performed, which may increase selectivity over conventional techniques while producing desired etch rates to maintain throughput.

In order to maintain the etch rate during operation 420, method 400 may include utilizing one or more precursors to reduce and/or remove etch byproduct that may result from the etching. If left untreated, etch byproduct may begin to accumulate on surfaces in the processing region. With increased amounts of etch byproduct, the etching reaction may become unfavorable and/or may begin to selectively etch the etch byproduct. In embodiments, the etch rate of the material to be removed may reduce or stop entirely. Additionally, the presence of etch byproduct may begin to impart residue to the structure being etched, thereby contaminating the structure. As such, the present technology may successfully control the etch byproduct and allow the etching operation to continue efficiently.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a boron-containing etchant precursor to a processing region of a semiconductor processing chamber, wherein a substrate is housed within the processing region;
providing a hydrogen-containing precursor, helium, or both to the processing region with the boron-containing etchant precursor;
contacting the substrate with the boron-containing etchant precursor and the hydrogen-containing precursor; and
selectively removing at least a portion of a first material on the substrate relative to a second material second material on the substrate while removing an etch byproduct from one or more surfaces of the processing region.

2. The semiconductor processing method of claim 1, wherein the boron-containing etchant precursor further comprises chlorine.

3. The semiconductor processing method of claim 1, wherein the boron-containing etchant precursor comprises boron trichloride (BCl₃).

4. The semiconductor processing method of claim 1, wherein the hydrogen-containing precursor comprises diatomic hydrogen (H₂).

5. The semiconductor processing method of claim 1, further comprising:
providing an oxygen-containing precursor to the processing region with the boron-containing etchant precursor.

6. The semiconductor processing method of claim 1, wherein the processing region is maintained plasma-free.

7. The semiconductor processing method of claim 1, wherein a flow rate of the hydrogen-containing precursor, a flow rate of helium, or both are pulsed.

8. The semiconductor processing method of claim 1, wherein a flow rate ratio of the hydrogen-containing precursor relative to a flow rate of the hydrogen-containing precursor and/or a flow rate of helium is between about 1:10 and about 10:1.

9. The semiconductor processing method of claim 1, wherein a temperature is maintained at greater than or about 50° C.

10. The semiconductor processing method of claim 1, wherein a pressure is maintained at greater than or about 0.5 Torr.

11. A semiconductor processing method comprising:
providing a boron-containing etchant precursor to a processing region of a semiconductor processing chamber, wherein a substrate is housed within the processing region;
contacting the substrate with the boron-containing etchant precursor;
selectively removing at least a portion of a first material relative to a second material, wherein removing the portion of the first material is performed plasma-free, and wherein removing the portion of the first material forms an etch byproduct on one or more surfaces in the processing region;
providing a hydrogen-containing precursor to the processing region; and
contacting surfaces in the processing region with the hydrogen-containing precursor, helium, or both, wherein the contacting removes a boron-containing byproduct from one or more surfaces in the processing region.

12. The semiconductor processing method of claim 11, wherein the etch byproduct comprises a boron-and-oxygen-containing material or a boron-and-carbon-containing material.

13. The semiconductor processing method of claim 11, wherein the hydrogen-containing precursor comprises diatomic hydrogen (H₂).

14. The semiconductor processing method of claim 11, further comprising:
providing a fluorine-containing precursor to the processing region with the hydrogen-containing precursor.

15. The semiconductor processing method of claim 14, wherein the fluorine-containing precursor comprises nitrogen trifluoride (NF₃).

16. The semiconductor processing method of claim 14, further comprising:
forming plasma effluents of the hydrogen-containing precursor, the fluorine-containing precursor, or both.

17. A semiconductor processing method comprising:
providing a boron-containing etchant precursor to a processing region of a semiconductor processing chamber, wherein a substrate is housed within the processing region;
contacting the substrate with the boron-containing etchant precursor;
selectively removing at least a portion of a first material relative to a second material, wherein removing the portion of the first material is performed plasma-free, and wherein removing the portion of the first material forms an etch byproduct on one or more surfaces in the processing region; and
contacting surfaces in the processing region with plasma effluents of a hydrogen-containing precursor, helium, or both, wherein the contacting removes a boron-containing byproduct from one or more surfaces in the processing region.

18. The semiconductor processing method of claim 17, wherein the plasma effluents of the hydrogen-containing precursor are formed in a remote plasma system.

19. The semiconductor processing method of claim 17, wherein the plasma effluents of the hydrogen-containing precursor are formed in the processing region.

20. The semiconductor processing method of claim 17, wherein a temperature is maintained at less than or about 200° C.
